(19) United States
(12) Patent Application Publication
(10) Pub. No.: US 2025/0105115 A1
(43) Pub. Date: Mar. 27, 2025

(54) Corner Reinforcement Structure for Package Interconnect

(71) Applicant: Taiwan Semiconductor Manufacturing Company, Ltd., Hsin-Chu (TW)

(72) Inventors: Chia-Jen Cheng, Taipei County (TW); Kuo-Ching Hsu, Taipei (TW)

(21) Appl. No.: 18/472,695

(22) Filed: Sep. 22, 2023

(51) Int. Cl. H01L 23/498; H01L 21/48; H01L 21/52; H01L 23/31; H01L 25/065

(52) U.S. Cl. CPC H01L 23/49816; H01L 21/4853; H01L 21/52; H01L 23/3128; H01L 25/0655

(57) ABSTRACT

A semiconductor structure includes a conductive bump disposed between a substrate and a board; an isolation member disposed over the board and surrounding the conductive bump and the substrate; a metallic member disposed between the isolation member and the conductive bump; and a solder disposed between the substrate and the board and configured to attach the metallic member to the substrate and the board. A method of manufacturing a semiconductor structure includes disposing a first solder on a first surface of a substrate; disposing a metallic member to the first surface of the substrate by the first solder; disposing a second solder on a board; and bonding the metallic member to the board by the second solder.

### PRIORITY CLAIM AND CROSS-REFERENCE

This is a non-provisional application of and claims the benefit of U.S. Provisional Patent Application Ser. No. 63/506,649, filed Jun. 7, 2023, and U.S. Provisional Patent Application Ser. No. 63/510,552, filed Jun. 27, 2023, each of which is hereby incorporated by reference in its entirety.

### BACKGROUND

The semiconductor industry has experienced rapid growth due to ongoing improvements in integration density of a variety of components. To accommodate miniaturized scales of semiconductor devices, various technologies and applications have been developed for wafer-level packaging, involving greater numbers of different components with different functions. Improvement in integration density has resulted from iterative reduction of minimum feature size, which allows more components to be integrated into a given area.

In packaging of integrated circuits, semiconductor dies may be disposed through bonding, and the semiconductor dies may be bonded to other package components such as package substrates. A conductive bump is disposed between a substrate and a board, and an isolation member including an encapsulating material is disposed over the board and surrounds the conductive bump and the substrate. However, there are many challenges to be overcome in order to fully leverage 3DIC technology.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, dimensions of the various features may be arbitrarily increased or reduced for clarity of discussion.

FIG. 1 is a cross-sectional view of a semiconductor structure in accordance with some embodiments of the present disclosure.

FIG. 2 is an enlarged cross-sectional view of a portion of a semiconductor structure in accordance with some embodiments of the present disclosure.

FIGS. 3-7 are top cross-sectional views of a semiconductor structure in accordance with some embodiments of the present disclosure.

FIG. 8 is a cross-sectional view of a semiconductor structure in accordance with some embodiments of the present disclosure.

FIG. 9 is an enlarged cross-sectional view of a portion of a semiconductor structure in accordance with some embodiments of the present disclosure.

FIG. 10 is a flow diagram of a method of manufacturing a semiconductor structure in accordance with some embodiments of the present disclosure.

FIG. 11 is a flow diagram of a method of manufacturing a semiconductor structure in accordance with some embodiments of the present disclosure.

FIGS. 12-22 are cross-sectional views of one or more stages of the method of manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard variation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Other features and processes may also be included. For example, testing structures may be included to aid in verification testing of 3D packaging or 3DIC devices. The testing structures may include, for example, test pads formed in a redistribution layer or on a substrate that allows the testing of the 3D package or 3DIC device, use of probes and/or probe cards, and the like. The verification testing may be performed on intermediate structures as well as a final structure. Additionally, the structures and methods disclosed herein may be used in conjunction with testing methodologies that incorporate intermediate verification of known good dies to increase yields and decrease costs.

In the present disclosure, a semiconductor structure and a method of manufacturing a semiconductor structure are provided. A semiconductor device includes a metallic member disposed between a substrate and a board, a first solder disposed between the substrate and the metallic member, and a second solder disposed between the board and the metallic member.

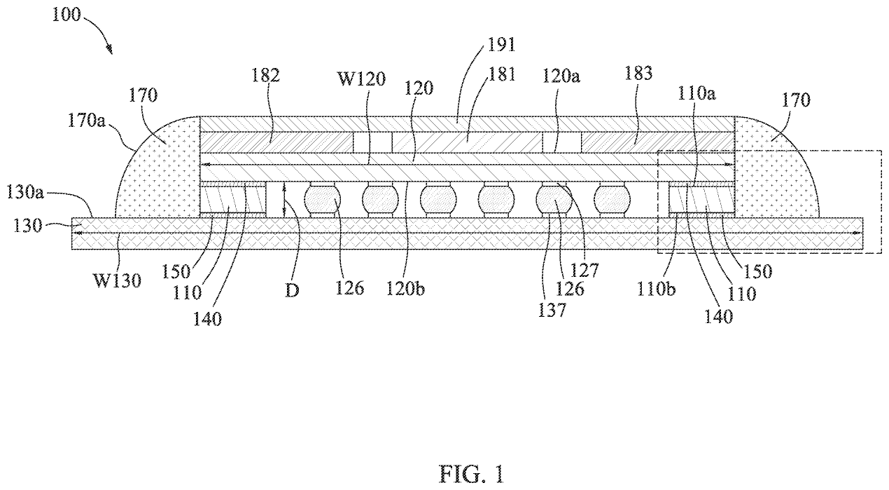

FIG. 1 is a cross-sectional view of a first semiconductor structure 100 in accordance with some embodiments of the present disclosure. Referring to FIG. 1, the first semiconductor structure 100 includes a metallic member 110 disposed between a substrate 120 and a board 130. In some embodiments, the board 130 serves as a package component. In some embodiments, the board 130 is a printed circuit board (PCB). Although not illustrated, in some embodiments, the board 130 may also include conductive interconnections (not shown) such as pads (not shown) at a surface of the board 130, and conductive traces, vias, conductive pipes, or the like built inside the board 130.

In some embodiments, the substrate 120 is a semiconductor substrate, such as a bulk semiconductor, a semiconductor-on-insulator (SOI) substrate, or the like, and may be doped (e.g., with a p-type or an n-type dopant) or undoped. The substrate 120 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate, may also be used. In some embodiments, the semiconductor material of the substrate 120 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. In some embodiments, the substrate 120 is a silicon substrate. In some embodiments, the substrate 120 is organic substrate. In some embodiments, the organic substrate includes ABF (ajinomoto build-up film), BT (bismaleimide-triazine), prepreg, polyimide, epoxy, Cu, Ni, Au, Ag, Solder, ceramics, or combinations thereof.

In some embodiments, the metallic member 110 is disposed between the substrate 120 and the board 130. In some embodiments, the metallic member 110 is disposed on the board 130 and disposed under the substrate 120. The metallic member 110 includes metallic material such as copper, aluminum, nickel, palladium, silver, gold, or an alloy thereof. In some embodiments, the substrate 120 includes a first surface 120a and a second surface 120b opposite to the first surface 120a. In some embodiments, the metallic member 110 is disposed at or under the second surface 120b of the substrate 120.

In some embodiments, a first solder 140 is disposed between the substrate 120 and the metallic member 110 and is configured to attach the metallic member 110 to the substrate 120. In some embodiments, the first solder 140 is in contact with the substrate 120 and the metallic member 110. In some embodiments, the first solder 140 is electrically coupled to the metallic member 110. In some embodiments, the first solder 140 includes any soldering material, such as lead-free solder or the like. The first solder 140 is reflowed and provides mechanical and electrical connections between the substrate 120 and the metallic member 110.

In some embodiments, a second solder 150 is disposed between the metallic member 110 and the board 130 and is configured to attach the metallic member 110 to the board 130. In some embodiments, the second solder 150 is in contact with the metallic member 110 and the board 130. In some embodiments, the second solder 150 is electrically coupled to the metallic member 110. In some embodiments, the metallic member 110 is sandwiched between the first solder 140 and the second solder 150. In some embodiments, the first solder 140, the metallic member 110 and the second solder 150 are stacked between the substrate 120 and the board 130. In some embodiments, the second solder 150 includes any soldering material, such as lead-free solder or the like. In some embodiments, the solder material of the first solder 140 is the same as or different from the soldering material of the second solder 150. The second solder 150 is reflowed and provides mechanical and electrical connections between the board 130 and the metallic member 110. In some embodiments, a total height of the metallic member 110, the first solder 140 and the second solder 150 may be given by a distance D between the substrate 120 and the board 130.

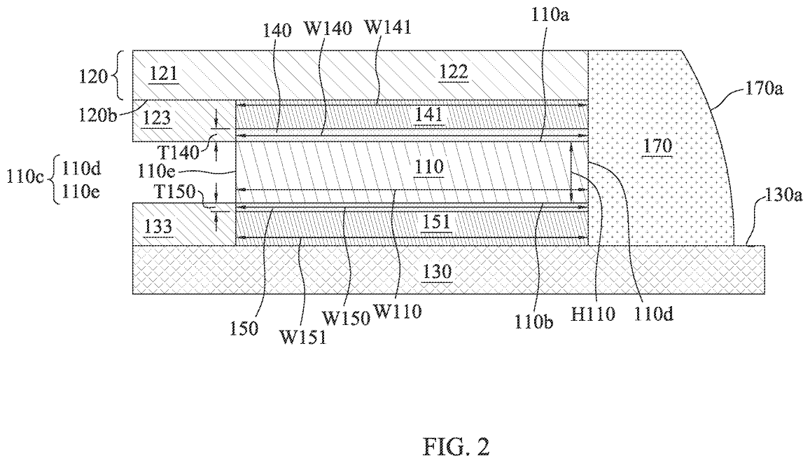

FIG. 2 is an enlarged cross-sectional view of a portion of the first semiconductor structure 100 in accordance with some embodiments of the present disclosure. Referring to FIGS. 1 and 2, in some embodiments, a first width W110 of the metallic member 110 the same as a second width W140 of the first solder 140. In some embodiments, the first width W110 of the metallic member 110 is the same as a third width W150 of the second solder 150.

In some embodiments, the first width W110 of the metallic member 110 is about 200 μm to about 10,000 μm. When the first width W110 of the metallic member 110 is less than 200 μm, the metallic member 110 does not significantly improve the drop test reliability of the first semiconductor structure 100. When the first width W110 of the metallic member 110 is greater than 10,000 μm, the first semiconductor structure 100 is not easy to miniaturize. In some embodiments, a first height H110 of the metallic member 110 is about 10 μm to about 1,000 μm. When the first height H110 of the metallic member 110 is less than 10 μm, the metallic member 110 does not significantly improve the drop test reliability of the first semiconductor structure 100. When the first height H110 of the metallic member 110 is greater than 1,000 μm, the first semiconductor structure 100 is not easy to miniaturize. In some embodiments, a first thickness T140 of the first solder 140 is about 10 μm to about 100 μm. When the first thickness T140 of the first solder 140 is less than 10 μm, the metallic member 110 may not be securely attached to the substrate 120. When the first thickness T140 of the first solder 140 is greater than 100 μm, the first semiconductor structure 100 is not easy to miniaturize. In some embodiments, a second thickness T150 of the second solder 150 is about 10 μm to about 100 μm. When the second thickness T150 of the second solder 150 is less than 10 μm, the metallic member 110 may not be securely attached to the board 130. When the second thickness T150 of the second solder 150 is greater than 100 μm, the first semiconductor structure 100 is not easy to miniaturize.

In some embodiments, the substrate 120 includes a central portion 121 and a peripheral portion 122, and the metallic member 110 is disposed at the peripheral portion 122. In some embodiments, the metallic member 110 is away from the central portion 121.

In some embodiments, the metallic member 110 includes a third surface 110a facing the substrate 120, a fourth surface 110b facing the board 130, and a fifth surface 110c connecting the third surface 110a and the fourth surface 110b. In some embodiments, the first solder 140 is attached to the third surface 110a of the metallic member 110, and the second solder 150 is attached to the fourth surface 110b of the metallic member 110. In some embodiments, the fifth surface 110c is separate from the first solder 140 and the second solder 150.

In some embodiments, a first conductive pad 141 is disposed between the substrate 120 and the first solder 140. In some embodiments, the first solder 140 is disposed between the first conductive pad 141 and the metallic member 110. In some embodiments, the first conductive pad 141 is in contact with the substrate 120 and the first solder 140. In some embodiments, the first conductive pad 141 includes conductive material such as copper, aluminum, nickel, palladium, silver, gold, or an alloy thereof. In some embodiments, the conductive material included in the first conductive pad 141 is the same as or different from the metallic material of the metallic member 110. In some embodiments, the first width W110 of the metallic member 110 the same as a fourth width W141 of the first conductive pad 141.

In some embodiments, a second conductive pad 151 is disposed between the board 130 and the second solder 150. In some embodiments, the second solder 150 is disposed between the second conductive pad 151 and the metallic member 110. In some embodiments, the second conductive pad 151 is in contact with the board 130 and the second solder 150. In some embodiments, the second conductive pad 151 includes a conductive material such as copper, aluminum, nickel, palladium, silver, gold, or an alloy thereof. In some embodiments, the conductive material included in the second conductive pad 151 is the same as or different from the metallic material of the metallic member 110. In some embodiments, the conductive material included in the second conductive pad 151 is the same as or different from the conductive material included in the first conductive pad 141. In some embodiments, the first width W110 of the metallic member 110 is the same as a fifth width W151 of the second conductive pad 151. In some embodiments, the fourth width W141 of the first conductive pad 141 is the same as the fifth width W151 of the second conductive pad 151.

In some embodiments, an isolation member 170 is disposed over the board 130 and surrounds the metallic member 110, the first solder 140, the second solder 150, and the substrate 120. In some embodiments, the isolation member 170 is in contact with the metallic member 110, the first solder 140 and the second solder 150. In some embodiments, the isolation member 170 is configured to encapsulate the first semiconductor structure 100. In some embodiments, the isolation member 170 includes an underfill, a glue, a resin, an epoxy, and/or the like. In some embodiments, an outer surface 170a of the isolation member 170 is curved.

In some embodiments, a sixth width W130 of the board 130 is greater than a seventh width W120 of the substrate 120. In some embodiments, the board 130 includes an exposed portion 130a exposed through the isolation member 170 and the substrate 120. In some embodiments, the exposed portion 130a surrounds the isolation member 170, the metallic member 110, the first solder 140, the second solder 150, and the substrate 120.

Referring back to FIG. 1, in some embodiments, a conductive bump 126 is disposed between the substrate 120 and the board 130 and adjacent to the metallic member 110. In some embodiments, the conductive bump 126 is in contact with the substrate 120 and the board 130. In some embodiments, the conductive bump 126 is electrically connected to the substrate 120 and the board 130. In some embodiments, the substrate 120 and the board 130 are electrically connected to each other through the conductive bump 126. In some embodiments, the conductive bump 126 may be a contact bump, a solder bump, a ball grid array (BGA) ball, a controlled collapse chip connection (C4) bump, a microbump, a metal pillar, or the like. In some embodiments, the conductive bump 126 includes conductive material such as tin (Sn), silver (Ag), lead-free tin (lead-free Sn), copper (Cu), or combinations thereof. In some embodiments, the conductive bump 126 has a spherical, hemispherical or cylindrical shape. In some embodiments, a plurality of conductive bumps 126 are disposed in the central portion 121 of the substrate 120.

In some embodiments, a first flux 127 is disposed on the substrate 120 and is attached to the conductive bump 126. In some embodiments, a second flux 137 is disposed on the board 130 and is attached to the conductive bump 126. In some embodiments, the first flux 127 and the second flux 137 are omitted.

In some embodiments, the metallic member 110 is disposed between the isolation member 170 and the conductive bump 126. In some embodiments, the isolation member 170 surrounds the conductive bump 126. In some embodiments, the conductive bump 126 is disposed between adjacent metallic members 110.

In some embodiments, the fifth surface 110c includes a first side 110d and a second side 110e opposite to the first side 110d. In some embodiments, the first side 110d of the fifth surface 110c faces the isolation member 170 and is disposed away from the conductive bump 126. In some embodiments, the first side 110d of the fifth surface 110c is in contact with the isolation member 170. In some embodiments, the second side 110e of the fifth surface 110c is disposed away from the isolation member 170 and is adjacent to the conductive bump 126.

In some embodiments, the substrate 120 further includes a first solder resist layer 123. In some embodiments, the first solder resist layer 123 is a solder mask. In some embodiments, the first solder resist layer 123 is disposed on the second surface 120b of the substrate 120. In some embodiments, the first solder resist layer 123 includes an electrically insulating, low surface tension material. The first solder resist layer 123 may initially cover all portions of the second surface 120b of the substrate 120, with the exception of openings (not shown) receiving the conductive bump 126. In some embodiments, the first solder resist layer 123 is in contact with the conductive bump 126. In some embodiments, at least a portion of the first solder resist layer 123 is between the conductive bump 126 and the first solder 140. In some embodiments, the first solder resist layer 123 is disposed adjacent to and in contact with the first solder 140. In some embodiments, the first solder resist layer 123 is disposed adjacent to and in contact with the first conductive pad 141. In some embodiments, the isolation member 170 surrounds the first solder resist layer 123.

In some embodiments, the board 130 further includes a second solder resist layer 133. In some embodiments, the second solder resist layer 133 is a solder mask. In some embodiments, the second solder resist layer 133 is disposed on the board 130. In some embodiments, the second solder resist layer 133 includes an electrically insulating, low surface tension material. The second solder resist layer 133 may initially cover all portions of the board 130, with the exception of openings (not shown) receiving the conductive bump 126. In some embodiments, the second solder resist layer 133 is in contact with the conductive bump 126. In some embodiments, at least a portion of the second solder resist layer 133 is between the conductive bump 126 and the second solder 150. In some embodiments, the second solder resist layer 133 is disposed adjacent to and in contact with the second solder 150. In some embodiments, the second solder resist layer 133 is disposed adjacent to and in contact with the second conductive pad 151. In some embodiments, the isolation member 170 surrounds the second solder resist layer 133.

In some embodiments, a first die 181 is disposed over the substrate 120, and the substrate 120 is disposed between the first die 181 and the first solder 140. In some embodiments, the substrate 120 is disposed between the first die 181 and the conductive bump 126. In some embodiments, the isolation member 170 surrounds the first die 181.

The first die 181 may be a logic die (e.g., a central processing unit, a microcontroller, etc.), a memory die (e.g., a dynamic random-access memory (DRAM) die, a static random-access memory (SRAM) die, etc.), a power management die (e.g., a power management integrated circuit (PMIC) die), a radio frequency (RF) die, a sensor die, a micro-electro-mechanical-system (MEMS) die, a signal processing die (e.g., a digital signal processing (DSP) die), a front-end die (e.g., an analog front-end (AFE) die), the like, or a combination thereof. The first die 181 can be an electronic integrated circuit (EIC) chip. In some embodiments, the first die 181 can provide required electronic functions of the first semiconductor structure 100. In some embodiments, an adhesive layer or a flux (not shown) is disposed between the first die 181 and the substrate 120. In some embodiments, the adhesive layer includes a die attach film (DAF) or another material having adhesive properties.

In some embodiments, a second die 182 and a third die 183 are disposed over the substrate 120 and adjacent to the first die 181. In some embodiments, the isolation member 170 surrounds the first die 181, the second die 182 and the third die 183. In some embodiments, the first die 181 is spaced apart from the second die 182 and the third die 183.

Each of the second die 182 and the third die 183 may be a logic die (e.g., a central processing unit, a microcontroller, etc.), a memory die (e.g., a dynamic random-access memory (DRAM) die, a static random-access memory (SRAM) die, etc.), a power management die (e.g., a power management integrated circuit (PMIC) die), a radio frequency (RF) die, a sensor die, a micro-electro-mechanical-system (MEMS) die, a signal processing die (e.g., a digital signal processing (DSP) die), a front-end die (e.g., an analog front-end (AFE) die), the like, or a combination thereof. In some embodiments, the second die 182 and the third die 183 are memory dies. In some embodiments, adhesive layers are disposed between the second die 182 and the substrate 120 and between the third die 183 and the substrate 120. In some embodiments, the adhesive layer includes a die attach film (DAF) or another material having adhesive properties.

In some embodiments, a lid 191 is disposed over the first die 181 and surrounded by the isolation member 170. In some embodiments, the lid 191 serves as a heat spreader. The lid 191 may include metal. In some embodiments, the first die 181 is disposed between the lid 191 and the substrate 120. In some embodiments, the first die 181, the second die 182 and the third die 183 are disposed between the lid 191 and the substrate 120 and surrounded by the isolation member 170. In some embodiments, the isolation member 170 is attached to the lid 191, the substrate 120 and the board 130.

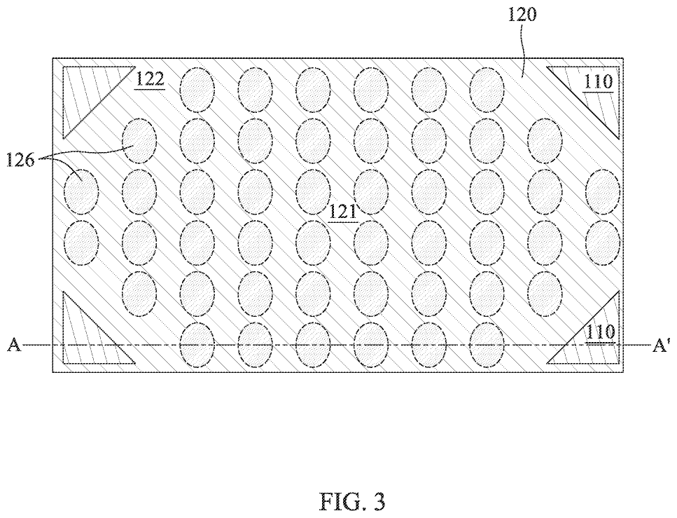

FIG. 3 is a top cross-sectional view of a portion of the first semiconductor structure 100 in accordance with some embodiments of the present disclosure. In some embodiments, FIG. 1 is a cross-sectional view of the first semiconductor structure 100 along a line A-A′ in FIG. 3. In some embodiments, referring to FIGS. 1, 2 and 3, the peripheral portions 122 of the substrate 120 are disposed at each corner of the substrate 120. A dimension, a size and a shape of the substrate 120 may be adjusted according to design requirements and are not particularly limited. In some embodiments, the shape of the substrate 120 is a rectangle or a square, and one of the metallic members 110 is disposed at each of the four corners of the substrate 120. In some embodiments, the metallic member 110 is disposed in the peripheral portion 122, and the conductive bump 126 is disposed in the central portion 121. In some embodiments, the four metallic members 110 are arranged in a rectangle or a square. In some embodiments, a shape of the metallic member 110 is designed to match the shape of the substrate 120. In some embodiments, the shape of the metallic member 110 is a circle, a triangle, a rectangle or a square from a top view perspective. In some embodiments, the shape of the metallic member 110 from the top view perspective is not particularly limited and may be adjusted according to actual needs. FIG. 3 illustrates only four metallic members 110 for clarity and simplicity, but such example is intended to be illustrative only, and is not intended to be limiting. In some embodiments, each metallic member 110 is electrically isolated from or independent of other metallic members 110. In some embodiments, six metallic members 110 are evenly distributed around the central portion 121.

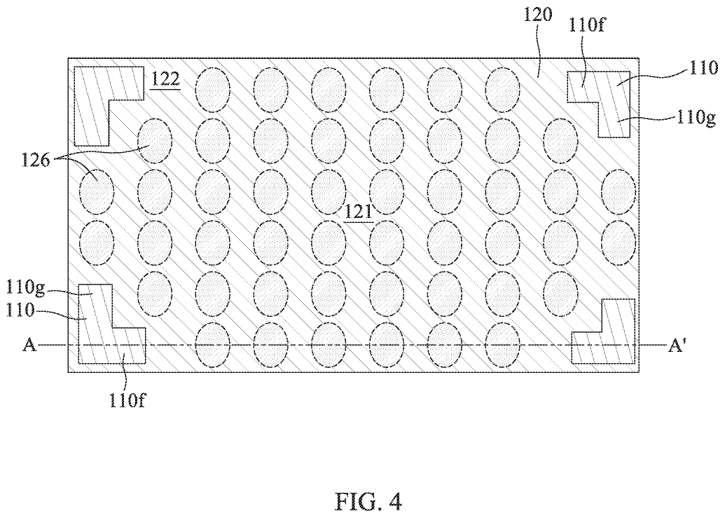

FIG. 4 is a top cross-sectional view of a portion of the first semiconductor structure 100 in accordance with some embodiments of the present disclosure. In some embodiments, FIG. 1 is a cross-sectional view of the first semiconductor structure 100 along a line A-A′ in FIG. 4. In some embodiments, referring to FIGS. 1, 2 and 4, the metallic member 110 is configured in an L shape from a top view perspective. In some embodiments, referring to FIGS. 1, 2 and 4, the metallic member 110 includes a first portion 110f and a second portion 110g adjacent to the first portion 110f. In some embodiments, the first portion 110f and the second portion 110g are continuous and attached to each other.

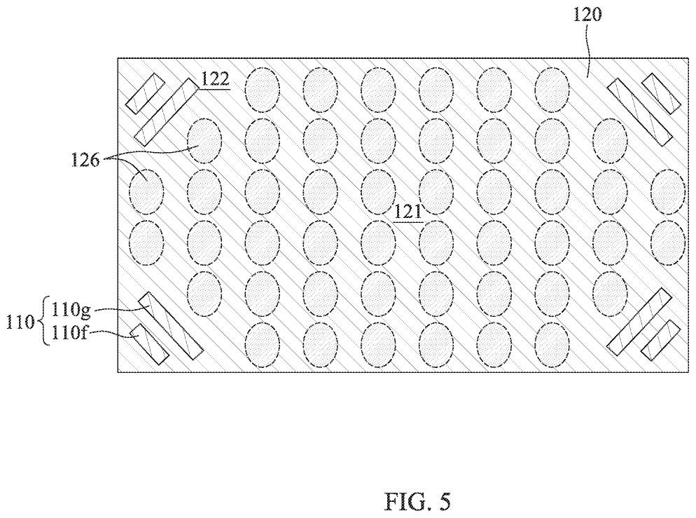

FIG. 5 is a top cross-sectional view of a portion of the first semiconductor structure 100 in accordance with some embodiments of the present disclosure. In some embodiments, referring to FIG. 5, the first portion 110f and the second portion 110g are separate and adjacent to each other. In some embodiments, the first portion 110f and the second portion 110g are parallel to each other.

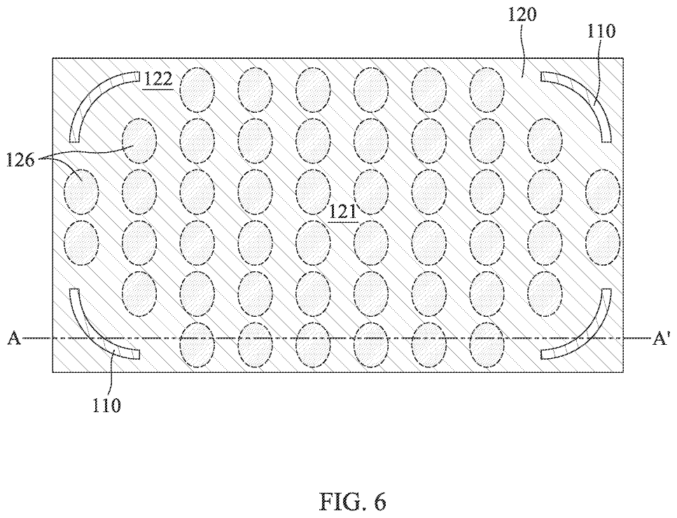

FIG. 6 is a top cross-sectional view of a portion of the first semiconductor structure 100 in accordance with some embodiments of the present disclosure. In some embodiments, FIG. 1 is a cross-sectional view of the first semiconductor structure 100 along a line A-A′ in FIG. 6. In some embodiments, referring to FIGS. 1, 2 and 6, the metallic member 110 has an arc shape from a top view perspective.

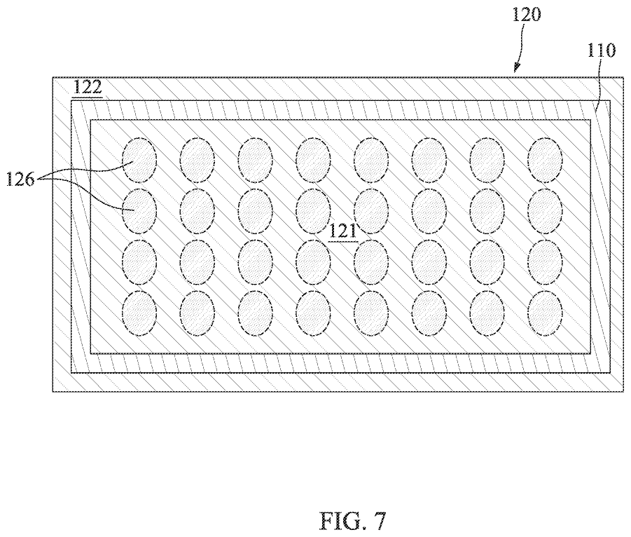

FIG. 7 is a top cross-sectional view of a portion of the first semiconductor structure 100 in accordance with some embodiments of the present disclosure. In some embodiments, the peripheral portion 122 surrounds the central portion 121. In some embodiments, the metallic member 110 surrounds the plurality of conductive bumps 126.

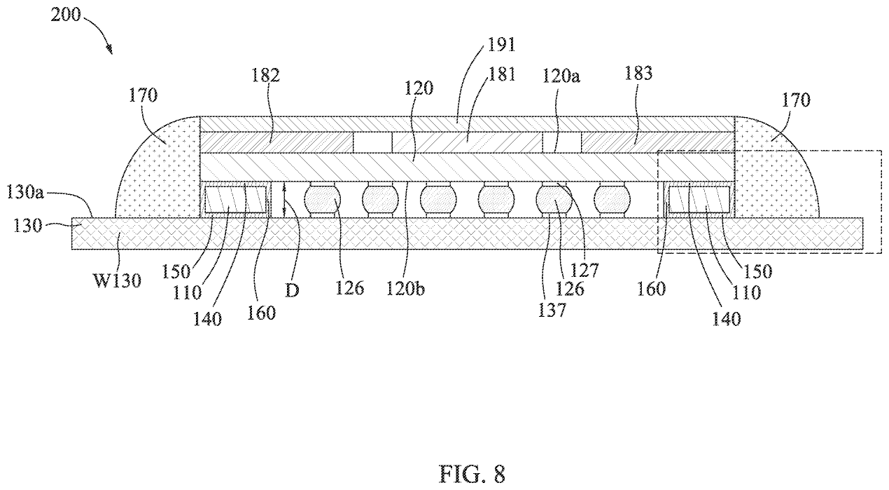

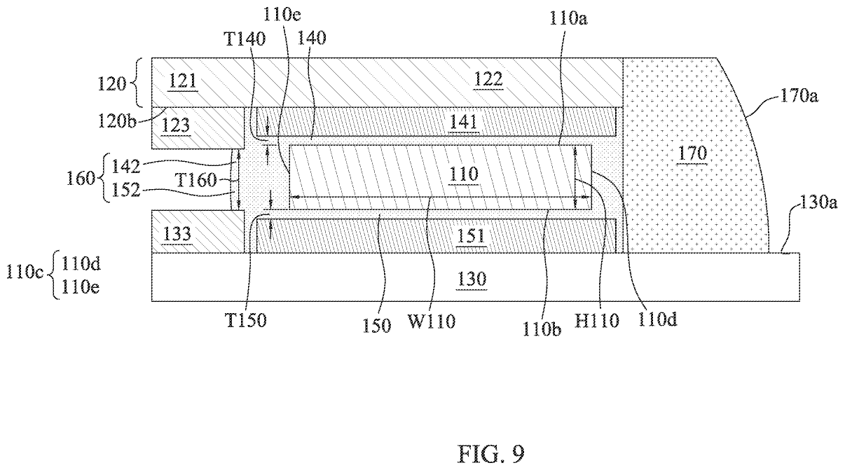

FIG. 8 is a cross-sectional view of a second semiconductor structure 200 in accordance with some embodiments of the present disclosure. FIG. 9 is a cross-sectional view of a portion of the second semiconductor structure 200 in accordance with some embodiments of the present disclosure. The second semiconductor structure 200 illustrated in FIGS. 8 and 9 is similar to the first semiconductor structure 100 illustrated in FIGS. 1 and 2, except that the second semiconductor structure 200 further includes a third solder 160 extending between the first solder 140 and the second solder 150. In some embodiments, the third solder 160 surrounds the metallic member 110. In some embodiments, the first solder 140, the second solder 150 and the third solder 160 surround the metallic member 110. In some embodiments, the third solder 160 is integral with the first solder 140 and the second solder 150.

In some embodiments, the third solder 160 is disposed between the first solder layer 123 and the second solder layer 133. In some embodiments, the third solder 160 is in contact with the metallic member 110, the first solder 140 and the second solder 150. In some embodiments, the third solder 160 is electrically connected to the metallic member 110, the first solder 140, and the second solder 150. In some embodiments, the third solder 160 is sandwiched between the first solder 140 and the second solder 150. In some embodiments, the third solder 160 includes any soldering material, such as lead-free solder or the like. In some embodiments, the solder material of the first solder 140 is the same as at least a portion of the solder material of the third solder 160. In some embodiments, the solder material of the second solder 150 is the same as at least a portion of the solder material of the third solder 160. The third solder 160 is reflowed and provides mechanical and electrical connections between the substrate 120 and the board 130. In some embodiments, a thickness of the third solder 160 is substantially the same as the distance D between the substrate 120 and the board 130.

In some embodiments, a portion of the third solder 160 is disposed between the metallic member 110 and the isolation member 170. In some embodiments, a portion of the third solder 160 is disposed between the metallic member 110 and the conductive bump 126. In some embodiments, the isolation member 170 is disposed over the board 130 and surrounds the metallic member 110, the first solder 140, the second solder 150, the third solder 160, and the substrate 120.

In some embodiments, the third solder 160 includes a first extending portion 142 extending along the fifth surface 110e of the metallic member 110 from the first solder 140. In some embodiments, the first extending portion 142 is integral with the first solder 140. In some embodiments, the third solder 160 includes a second extending portion 152 extending along the fifth surface 110e from the second solder 150. In some embodiments, the second extending portion 152 is integral with the second solder 150. In some embodiments, the third solder 160 covers the fifth surface 110e. In some embodiments, the fifth surface 110e is covered by the first extending portion 142 and the second extending portion 152.

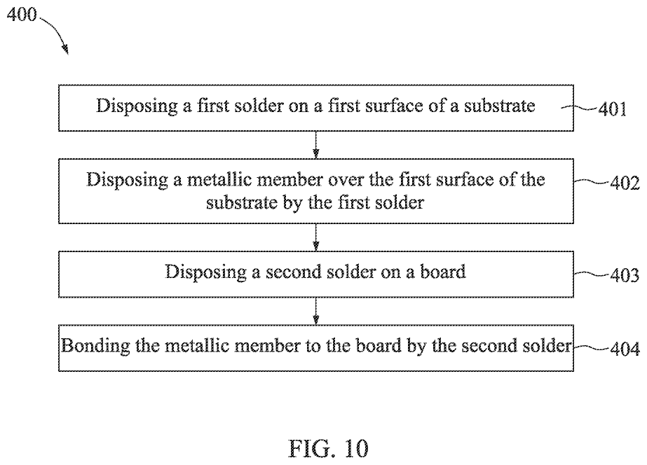

According to some embodiments of the present disclosure, a method for manufacturing a semiconductor structure is disclosed. In some embodiments, the first semiconductor structure 100 and the second semiconductor structure 200 are fabricated by a method 400. FIG. 10 is a flowchart of the method 400 in accordance with some embodiments. The method 400 includes a number of operations (401 to 404), and descriptions and illustrations are not deemed as a limitation to a sequence of the operations. Additional steps can be provided before, during, and after the operations shown in FIG. 10, and some of the operations described below can be replaced or eliminated in other embodiments of the method 400. An order of the operations may be interchangeable.

In operation 401, referring to FIG. 10, a first solder is disposed on a first surface of a substrate. In operation 402, a metallic member is disposed on the first surface of the substrate by the first solder. In operation 403, a second solder is disposed on a board. In operation 404, the metallic member is bonded to the board by the second solder.

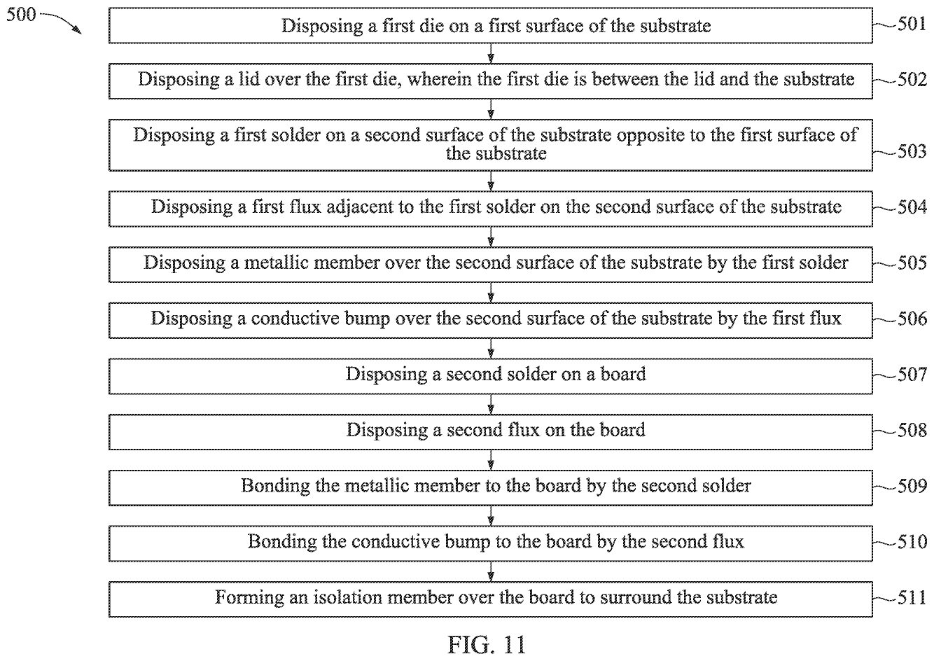

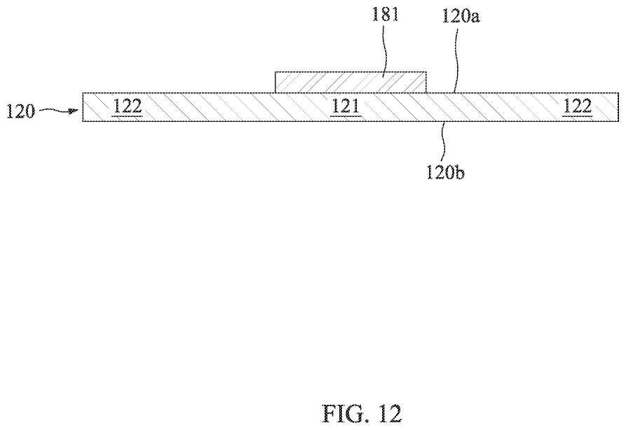

According to some embodiments of the present disclosure, another method for manufacturing a semiconductor structure is disclosed. In some embodiments, the first semiconductor structure 100 and the second semiconductor structure 200 are fabricated by a method 500. FIG. 11 is a flowchart of the method 500 in accordance with some embodiments. The method 500 includes a number of operations (501 to 511), and descriptions and illustrations are not deemed as a limitation to a sequence of the operations. Additional steps can be provided before, during, and after the operations shown in FIG. 11, and some of the operations described below can be replaced or eliminated in other embodiments of the method 500. An order of the operations may be interchangeable. FIGS. 12 to 22 are schematic cross-sectional views of one or more operations of the method 500 for manufacturing a semiconductor structure in accordance with some embodiments of the present disclosure.

The method 500 begins with operation 501. Operation 501 includes disposing a first die on a first surface of a substrate.

In some embodiments, the substrate 120 is provided as shown in FIG. 12. In some embodiments, the substrate 120 includes the first surface 120a and the second surface 120b opposite to the first surface 120a. In some embodiments, the first die 181 is disposed over the first surface 120a of the substrate 120. In some embodiments, an adhesive layer (not shown) is disposed over the first surface 120a of the substrate 120, and the first die 181 is disposed over the adhesive layer. In some embodiments, the first die 181 is disposed in the central portion 121 of the substrate 120. In some embodiments, the substrate 120 further includes the peripheral portion 122 adjacent to the central portion 121.

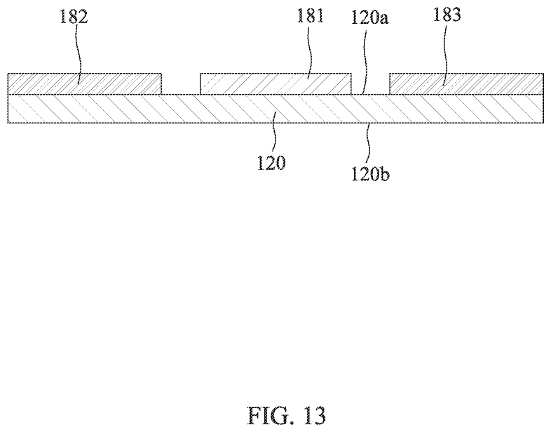

In some embodiments, referring to FIG. 13, the second die 182 is disposed adjacent to the first die 181. In some embodiments, the third die 183 is further disposed adjacent to the first die 181, wherein the first die 181 is disposed between the second die 182 and the third die 183. In some embodiments, the second die 182 and the third die 183 are disposed over the adhesive layer. In some embodiments, the second die 182 and the third die 183 are disposed in the peripheral portion 122 of the substrate 120.

The method 500 continues with operation 502. Operation 502 includes disposing a lid over the first die, wherein the first die is between the lid and the substrate.

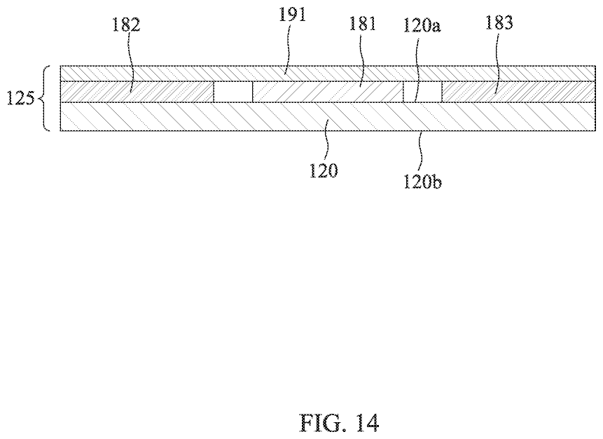

In some embodiments, referring to FIG. 14, the lid 191 is disposed over the first die 181 and the substrate 120. In some embodiments, the lid 191 is disposed over the first die 181, the second die 182 and the third die 183. In some embodiments, the lid 191 is attached to and covers the first die 181, the second die 182 and the third die 183. In some embodiments, a stack 125 including the substrate 120, the lid 191, and the first die 181 between the substrate 120 and the lid 191 is formed.

The method 500 continues with operation 503. Operation 503 includes disposing a first solder on the second surface of the substrate. In some embodiments, operation 503 of the method 500 is similar to operation 401 of the method 400.

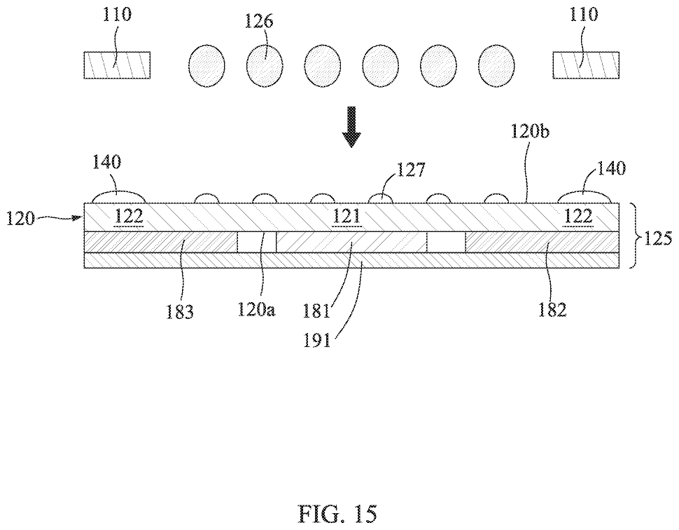

In some embodiments, the stack 125 is flipped over, and the second surface 120b becomes an upper surface. In some embodiments, referring to FIG. 15, a first solder 140 is disposed on the second surface 120b of the substrate 120. In some embodiments, the first solder 140 is disposed in the peripheral portion 122 of the substrate 120. In some embodiments, the metallic member 110 is disposed at a first position, and the second surface 120b faces the metallic member 110. In some embodiments, the firs position is at or adjacent to the peripheral portion 122. At the first position, the metallic member 110 is aligned with the first solder 140 disposed on the second surface 120b of the substrate 120. In some embodiments, a distance between the metallic member 110 and the first solder 140 is greater than 0.

The method 500 continues with operation 504. Operation 504 includes disposing a first flux adjacent to the first solder on the second surface of the substrate.

Still referring to FIG. 15, in some embodiments, the first flux 127 is disposed adjacent to the first solder 140 on the second surface 120b of the substrate 120. In some embodiments, the first flux 127 is disposed in the central portion 121 of the substrate 120. In some embodiments, conductive bumps 126 are disposed at a second position, and the second surface 120b faces the conductive bumps 126. In some embodiments, the second position is at or adjacent to the central portion 121. At the second position, the conductive bumps 126 are aligned with the first flux 127 disposed on the second surface 120b of the substrate 120. In some embodiments, a distance between the conductive bumps 126 and the first flux 127 is greater than 0.

The method 500 continues with operation 505. Operation 505 includes disposing a metallic member over the second surface of the substrate by the first solder. In some embodiments, operation 505 of the method 500 is similar to operation 402 of the method 400.

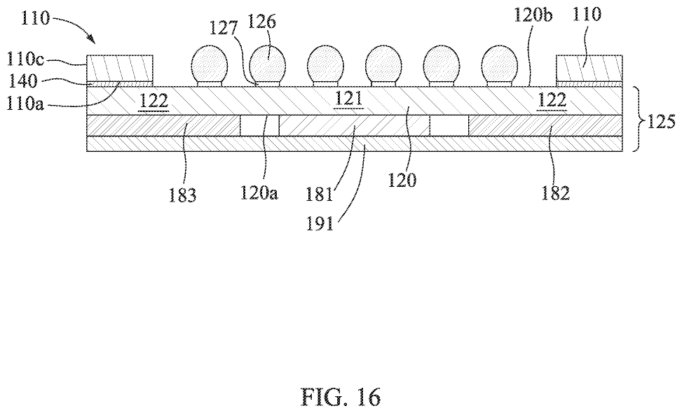

In some embodiments, referring to FIG. 16, the metallic member 110 is disposed on the second surface 120b of the substrate 120 by the first solder 140. In some embodiments, the first solder 140 is attached to the third surface 110a of the metallic member 110 and is isolated from a fifth surface 110c of the metallic member 110.

The method 500 continues with operation 506. Operation 506 includes disposing a conductive bump over the second surface of the substrate by the first flux.

In some embodiments, referring to FIG. 16, the conductive bumps 126 are disposed on the second surface 120b of the substrate 120 by the first flux 127. In some embodiments, the conductive bumps 126 are disposed in the central portion 121 of the substrate 120. In some embodiments, the conductive bumps 126 are disposed adjacent to the metallic member 110. In some embodiments, a bonding of the conductive bumps 126 to the substrate 120 and a bonding of the metallic member 110 to the substrate 120 are performed simultaneously.

The method 500 continues with operation 507. Operation 507 includes disposing a second solder on a board. In some embodiments, operation 507 of the method 500 is similar to operation 403 of the method 400. The method 500 continues with operation 508. Operation 508 includes disposing a second flux on the board.

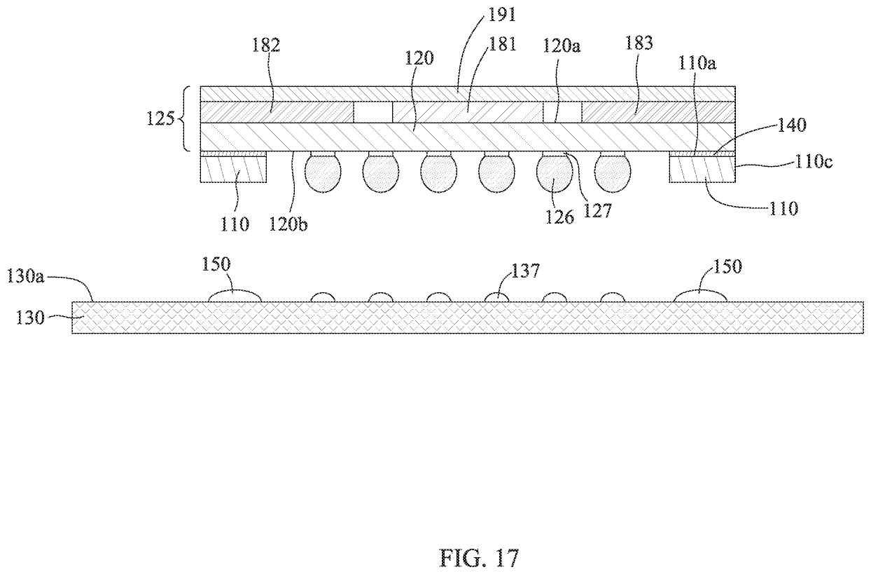

In some embodiments, referring to FIG. 17, the second solder 150 is disposed on the board 130. In some embodiments, the second flux 137 is disposed on the board 130 and adjacent to the second solder 150. In some embodiments, the board 130 includes an exposed portion 130a exposed through the second solder 150 and the second flux 137.

In some embodiments, the stack 125 having the metallic member 110 and the conductive bumps 126 disposed thereon is flipped over and disposed at a third position, such that the second surface 120b of the substrate 120 faces the board 130. At the third position, the metallic member 110 is aligned with the second solder 150 disposed on the board 130, and the conductive bumps 126 are aligned with the second flux 137 disposed on the board 130. In some embodiments, a distance between the metallic member 110 and the second solder 150 is greater than 0.

The method 500 continues with operation 509. Operation 509 includes bonding the metallic member to the board by the second solder. In some embodiments, operation 509 of the method 500 is similar to operation 403 of the method 400. The method 500 continues with operation 510. Operation 510 includes bonding the conductive bumps to the board by the second flux.

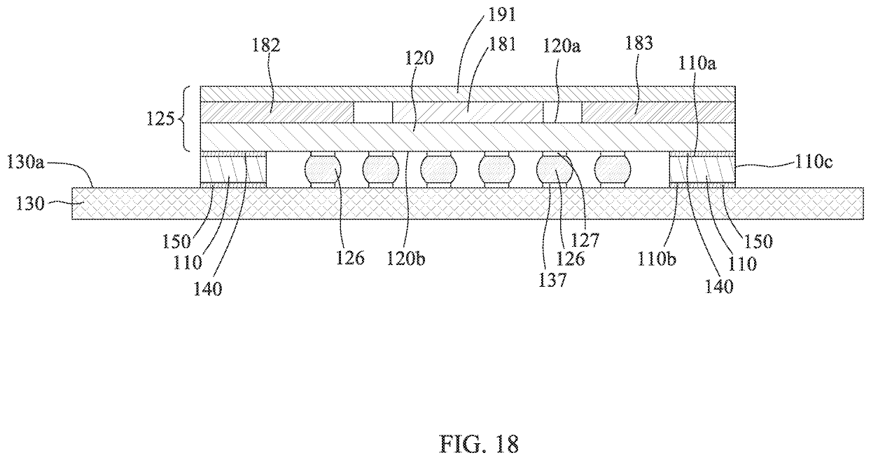

In some embodiments, referring to FIG. 18, the metallic member 110 is bonded to the board 130 by the second solder 150. In some embodiments, the conductive bumps 126 are bonded to the board 130 by the second flux 137. In some embodiments, the bonding of the conductive bumps 126 to the board 130 and the bonding of the metallic member 110 to the board 130 are performed simultaneously. In some embodiments, the exposed portion 130a of the board 130 is exposed through the substrate 120 from a top view perspective. In some embodiments, the third surface 110a of the metallic member 110 faces the substrate 120 and is attached to the first solder 140, and the fourth surface 110b of the metallic member 110 faces the board 130 and is attached to the second solder 150. In some embodiments, the fifth surface 110c of the metallic member 110 connecting the third surface 110a and the fourth surface 110b is exposed.

The method 500 continues with operation 511. Operation 511 includes forming an isolation member over the board to surround the substrate.

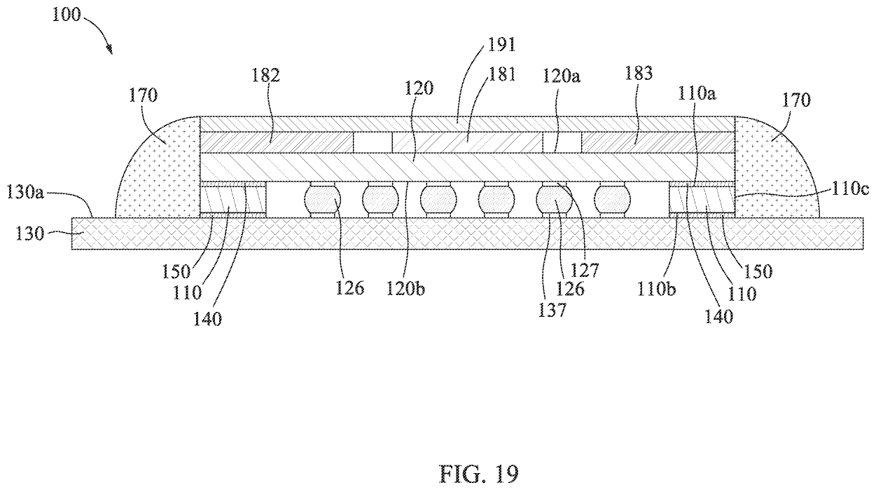

In some embodiments, referring to FIG. 19, the isolation member 170 is formed over the board 130 to surround the substrate 120. In some embodiments, the isolation member 170 is disposed adjacent to the metallic member 110. In some embodiments, the isolation member 170 is attached to the lid 191, the substrate 120, the first solder 140, the second solder 150, and the metallic member 110. In some embodiments, at least a portion of the fifth surface 110c of the metallic member 110 is in contact with the isolation member 170. In some embodiments, the exposed portion 130a of the board 130 is exposed through the substrate 120 and the isolation member 170 from a top view perspective. In some embodiments, the first semiconductor structure 100 is formed.

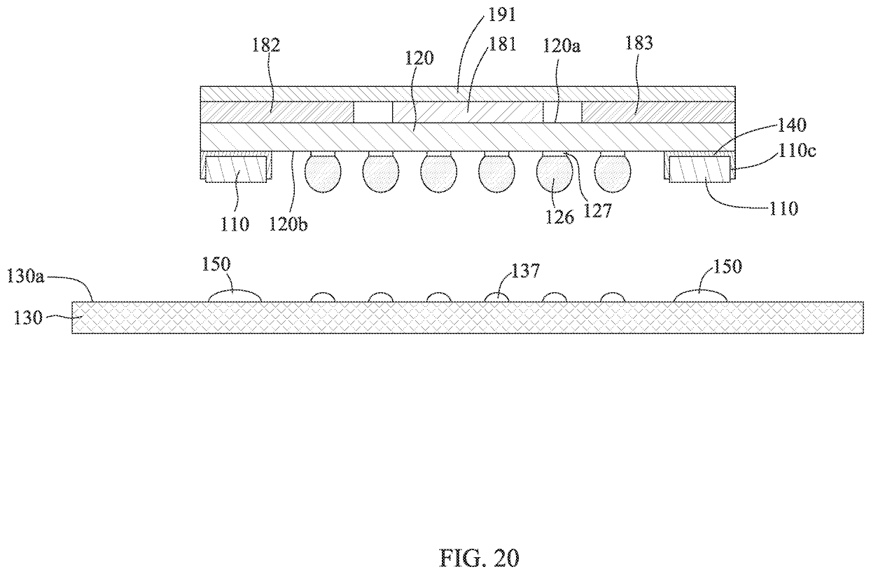

In some embodiments, referring to FIG. 20, in operation 505, the metallic member 110 is disposed on the substrate 120 by the first solder 140, and the first solder 140 extends along the fifth surface 110c and is in contact with at least a portion of the fifth surface 110c of the metallic member 110.

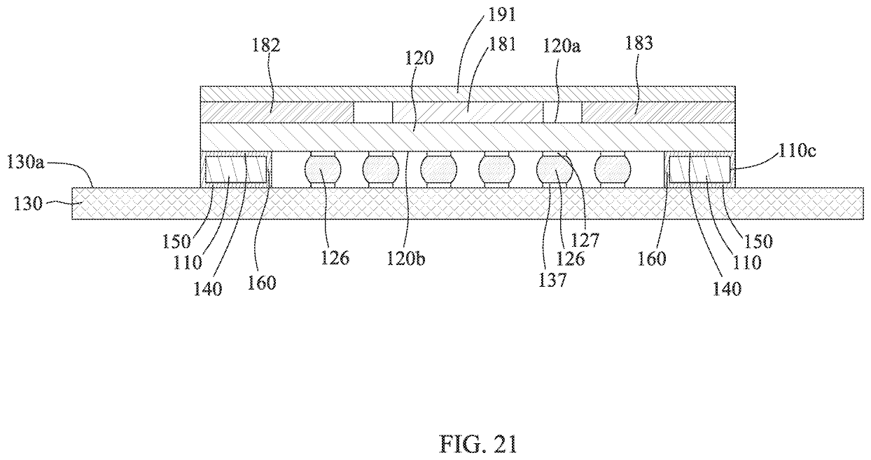

In some embodiments, referring to FIG. 21, in operation 509, the metallic member 110 is bonded to the board 130 by the second solder 150, and the second solder 150 extends along the fifth surface 110c and is in contact with at least a portion of the fifth surface 110c of the metallic member 110. In some embodiments, the first solder 140 and the second solder 150 surround the metallic member 110. In some embodiments, the first solder 140 and the second solder 150 cover the fifth surface 110c of the metallic member 110.

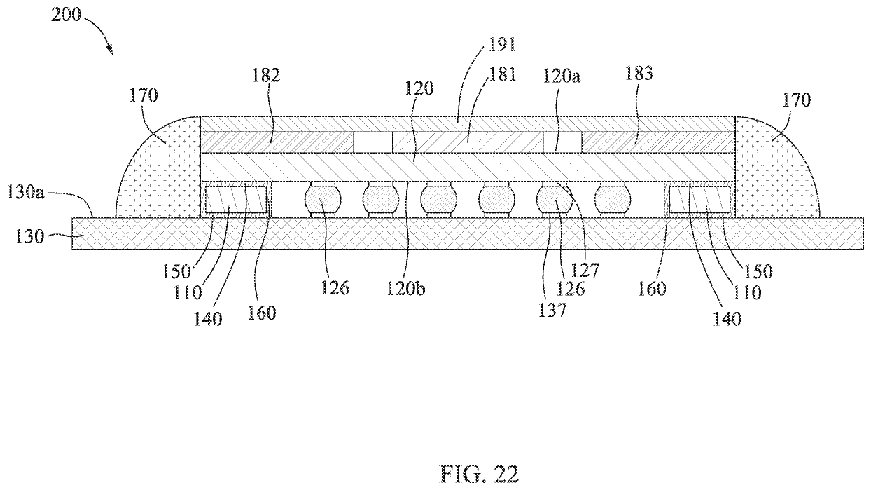

In some embodiments, referring to FIG. 22, in operation 511, the isolation member 170 is formed over the board 130 to surround the substrate 120, and the isolation member 170 and the metallic member 110 are separate. In some embodiments, a portion of the first solder 140 and/or a portion of the second solder 150 is disposed between the isolation member 170 and the metallic member 110.

Advanced IC packaging technologies have been developed to further reduce density and/or improve performance of integrated circuits (ICs), which are incorporated into many electronic devices. The present disclosure is generally directed to IC/semiconductor packaging, and more particularly, to corner structures for reinforcing interconnects between package components, such as solder ball structures that interconnect package components, such as substrates (e.g., a package substrate and a printed circuit board), of an IC package.

One aspect of this disclosure relates to a semiconductor structure. The semiconductor structure includes a metallic member disposed between a substrate and a board; a first solder disposed between the substrate and the metallic member; and a second solder disposed between the board and the metallic member.

In some embodiments, the semiconductor structure further includes a third solder extending between the first solder and the second solder, wherein the third solder surrounds the metallic member. In some embodiments, the third solder is integral with the first solder and the second solder. In some embodiments, the substrate includes a central portion and a peripheral portion, and the metallic member is disposed at the peripheral portion. In some embodiments, the semiconductor structure further includes an isolation member disposed over the board and surrounding the metallic member, the first solder, the second solder, and the substrate. In some embodiments, the isolation member is in contact with the metallic member, the first solder and the second solder. In some embodiments, the semiconductor structure includes an isolation member disposed over the board and surrounding the metallic member, the first solder, the second solder, the third solder and the substrate, wherein the third solder is disposed between the isolation member and the metallic member. In some embodiments, the semiconductor structure further includes a die disposed over the substrate, and the substrate is disposed between the die and the first solder. In some embodiments, the semiconductor structure further includes a conductive pad disposed between the substrate and the first solder.

One aspect of this disclosure relates to a semiconductor structure. The semiconductor structure includes a conductive bump disposed between a substrate and a board; an isolation member disposed over the board and surrounding the conductive bump and the substrate; a metallic member disposed between the isolation member and the conductive bump; and a solder disposed between the substrate and the board and configured to attach the metallic member to the substrate and the board.

In some embodiments, a total height of the metallic member and the solder is substantially identical to a distance between the substrate and the board. In some embodiments, the solder surrounds the metallic member.

An aspect of this disclosure relates to a method of manufacturing a semiconductor structure. The method includes disposing a first solder on a first surface of a substrate; disposing a metallic member on the first surface of the substrate by the first solder; disposing a second solder on a board; and bonding the metallic member to the board by the second solder.

In some embodiments, the method further includes disposing a die on a second surface of the substrate, wherein the second surface is opposite to the first surface; and disposing a lid over the die, wherein the die is between the lid and the substrate. In some embodiments, the die is disposed on the second surface of the substrate before the first solder is disposed on the first surface of the substrate. In some embodiments, the method further includes disposing a first flux adjacent to the first solder on the first surface of the substrate; disposing a conductive bump on the first surface of the substrate by the first flux; disposing a second flux on the board; and bonding the conductive bump to the board by the second flux.

In some embodiments, the bonding of the conductive bump to the board and the bonding of the metallic member to the board are performed simultaneously. In some embodiments, the metallic member includes a third surface facing the substrate, a fourth surface facing the board, and a fifth surface connecting the third surface and the fourth surface; the first solder is attached to the third surface of the metallic member; and the second solder is attached to the fourth surface of the metallic member. In some embodiments, the method further includes disposing the first solder and the second solder along the fifth surface to be in contact with the fifth surface of the metallic member. In some embodiments, the method further includes forming an isolation member over the board to surround the substrate; wherein the metallic member is disposed adjacent to the isolation member.

Package structures may be configured without corner reinforcement or with corner reinforcement, such as described herein. For example, a package may include a first substrate (e.g., the substrate 120, such as a package substrate or an interposer) and one or more chips/dies (e.g., the first die 181, the second die 182, and the third die 186, such as logic chips and memory chips (e.g., dynamic random-access memory (DRAM)). The chips are attached/bonded to the first substrate by any suitable interconnect/bonding structure. The package may further include a lid (e.g., the lid 191) disposed over the chips, such that the chips are between the lid and the first substrate. The package further includes a second substrate (e.g., the board 130, such as a printed circuit board (PCB)), and the first substrate is attached/bonded to the second substrate by solder ball/bump structures (e.g., the conductive bumps 126). In some embodiments, the solder ball structures include solder balls (e.g., conductive bumps 126), electrically conductive pads (e.g., a metal pad (e.g., the first flux 127) disposed on the first substrate and a metal pad (e.g., the second flux 137) disposed on the second substrate), and solder masks (e.g., the first solder resist layer 123 and/or the second solder resist layer 133). In such embodiments, a solder ball structure may include a solder ball (e.g., a respective conductive bump 126) disposed between electrically conductive pads (e.g., a respective first flux 127 and a respective second flux 137), where the electrically conductive pads are disposed in respective solder masks (e.g., the first solder resist layer 123 and the second solder resist layer 133, respectively). In a bottom view, the solder balls may be arranged in a pattern, which may be referred to as a ball grid array (BGA).

The package may include edge glue (e.g., the isolation member 170) at corners (e.g., the peripheral portions 122) of the package, and the edge glue may provide structural/mechanical reinforcement to the solder balls at edges and/or corners of the packages, in particular, at edges and/or corners of the first substrate. In a cross-sectional view, the edge glue may be disposed along sidewalls of the lid, the chips disposed at edges of the first substrate, the first substrate, and the solder balls disposed at the edges of the first substrate. The edge glue may further be disposed on the second substrate. It has been observed that structural/mechanical reinforcement of the edge/corner solder balls may degrade when the edge glue cracks. For example, as edge glue cracks, cracks may form at solder joints, such as between a solder ball and electrically conductive pads between which the solder ball is disposed, which degrades package reliability.

To provide additional structural/mechanical reinforcement to the solder balls at edges and/or corners of the packages, in particular, at edges and/or corners of the first substrate, the present disclosure configures the package with corner reinforcement structures (e.g., the metallic member 110 disposed between the first solder 140 and the second solder 150) in at least one corner of the package. In some embodiments, such as described above, all four package corners include the corner reinforcement structure. The corner reinforcement structure includes a metal spacer (e.g., the metallic member 110) disposed between electrically conductive pads (e.g., the first conductive pad 141 and the second conductive pad 151), where the electrically conductive pads may be disposed in respective solder masks (e.g., the first solder resist layer 123 and the second solder resist layer 133, respectively). The metal spacer is disposed in a solder layer (e.g., the first solder 140 and the second solder 150, and in some embodiments, the third solder 160), which may be disposed between the electrically conductive pads and the metal spacer. The metal spacer may include copper, nickel, silver, gold, other suitable metal, alloys thereof, or a combination thereof. The metal spacer may be a single metal layer or a multilayer metal structure. Dimensions of the corner reinforcement structure, such as dimensions of the metal spacer and/or spacings between the metal spacer and surrounding features, are disclosed herein that may optimize structural/mechanical reinforcement. In some embodiments, corner reinforcement structures (e.g., metal spacers thereof) are L-shaped. Other shapes and/or configurations of the corner reinforcement structures are contemplated, such as triangular shaped, slanted lines that extend between edges of the package, semi-circular shaped, or other shapes.

A packaging process flow that incorporates forming corner reinforcement structures may include attaching/bonding one or more chips to a frontside of the first substrate (e.g., FIG. 12 and FIG. 13) and forming the lid over the one or more chips (e.g., FIG. 17). The packaging process flow may include forming solder paste (e.g., the first solder 140) in corner reinforcement regions and flux (e.g., the first flux 127) on solder ball regions of a backside of the first substrate (e.g., FIG. 15 and FIG. 16) and forming metal spacers (e.g., the metallic members 110) on the solder paste and solder balls (e.g., the conductive bumps 126) on the flux (e.g., FIG. 15 and FIG. 16). The solder paste may surround the metal spacers. The packaging process flow may include forming solder paste (e.g., the second solder 150) in corner reinforcement regions and flux (e.g., the second flux 137) on solder ball regions of the second substrate (e.g., FIG. 17), attaching/bonding the first substrate to the second substrate (e.g., corner reinforcement regions and solder ball regions thereof) (e.g., FIG. 18), and forming edge glue (e.g., isolation member 170) along edges/corners of the first substrate and features attached to edges/corners thereof (e.g., FIG. 19).

In some embodiments, a package structure (e.g., the semiconductor structure 100 or the semiconductor structure 200) includes a first substrate (e.g., the substrate 120) and a chip (e.g., the first die 181, the second die 182, the third die 183, or a combination thereof) attached to a first surface (e.g., the surface 120A) of the first substrate. The package structure further includes an interconnect structure (e.g., conductive bumps 126) that connects a second surface (e.g., the surface 120b) of the first substrate to a second substrate (e.g., the board 130). The second surface is opposite the first surface. The package structure further includes a corner reinforcement structure (e.g., the metallic member 110 disposed between the first solder 140 and the second solder 150) between the second surface of the first substrate and the second substrate. The corner reinforcement structure is disposed in a corner region (e.g., the peripheral region 122) of the first substrate and the corner reinforcement structure is adjacent to the interconnect structure. In some embodiments, the package structure further includes a first electrically conductive pad (e.g., the first conductive pad 141) disposed on the second surface of the first substrate and a second electrically conductive pad (e.g., the second conductive pad 151) disposed on the second substrate. In some embodiments, the corner reinforcement structure may be between the first electrically conductive pad and the second electrically conductive pad. The corner reinforcement structure may include a metal spacer (e.g., the metallic member 110) disposed within a solder layer (e.g., the first solder 140 and the second solder 150, and in some embodiments, the third solder 160). In some embodiments, the solder layer is between the metal spacer and the first electrically conductive pad. In some embodiments, the solder layer is between the metal spacer and the second electrically conductive pad.

In some embodiments, a package structure (e.g., the semiconductor structure 100 or the semiconductor structure 200) includes a substrate (e.g., the substrate 120) having a first surface (e.g., the surface 120A) and a second surface (e.g., the surface 120B) opposite the first surface. The package structure further includes a chip (e.g., the first die 181, the second die 182, the third die 183, or a combination thereof) formed on the first surface of the substrate. The package structure further includes a solder ball grid array (e.g., conductive bumps 126) formed on the second surface of the substrate. The package structure further includes a solder reinforcement structure (e.g., the metallic member 110 disposed between the first solder 140 and the second solder 150) formed in a corner (e.g., the peripheral region 122) of the second surface of the substrate. The solder reinforcement structure includes a metal layer (e.g., the metallic member 110) disposed within a solder layer (e.g., the first solder 140 and the second solder 150, and in some embodiments, the third solder 160).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a metallic member disposed between a substrate and a board;
a first solder disposed between the substrate and the metallic member; and
a second solder disposed between the board and the metallic member.

2. The semiconductor structure of claim 1, further comprising a third solder extending between the first solder and the second solder, wherein the third solder surrounds the metallic member.

3. The semiconductor structure of claim 2, wherein the third solder is integral with the first solder and the second solder.

4. The semiconductor structure of claim 2, further comprising an isolation member disposed over the board and surrounding the metallic member, the first solder, the second solder, the third solder, and the substrate, wherein the third solder is disposed between the isolation member and the metallic member.

5. The semiconductor structure of claim 1, wherein the substrate includes a central portion and a peripheral portion, and the metallic member is disposed at the peripheral portion.

6. The semiconductor structure of claim 1, further comprising an isolation member disposed over the board and surrounding the metallic member, the first solder, the second solder, and the substrate.

7. The semiconductor structure of claim 6, wherein the isolation member is in contact with the metallic member, the first solder, and the second solder.

8. The semiconductor structure of claim 1, further comprising a die disposed over the substrate, wherein the substrate is disposed between the die and the first solder.

9. The semiconductor structure of claim 1, further comprising a conductive pad disposed between the substrate and the first solder.

10. A semiconductor structure, comprising:
a conductive bump disposed between a substrate and a board;
an isolation member disposed over the board and surrounding the conductive bump and the substrate;
a metallic member disposed between the isolation member and the conductive bump; and
a solder disposed between the substrate and the board and configured to attach the metallic member to the substrate and the board.

11. The semiconductor structure of claim 10, wherein a total height of the metallic member and the solder is substantially the same as a distance between the substrate and the board.

12. The semiconductor structure of claim 10, wherein the solder surrounds the metallic member.

13. A method of manufacturing a semiconductor structure, comprising:
disposing a first solder on a first surface of a substrate;
disposing a metallic member over the first surface of the substrate by the first solder;
disposing a second solder on a board; and
bonding the metallic member to the board by the second solder.

14. The method of claim 13, further comprising:
disposing a die on a second surface of the substrate, wherein the second surface is opposite to the first surface; and
disposing a lid over the die, wherein the die is between the lid and the substrate.

15. The method of claim 14, wherein the die is disposed on the second surface of the substrate before the first solder is disposed on the first surface of the substrate.

16. The method of claim 13, further comprising:
disposing a first flux adjacent to the first solder on the first surface of the substrate;
disposing a conductive bump over the first surface of the substrate by the first flux;
disposing a second flux on the board; and
bonding the conductive bump to the board by the second flux.

17. The method of claim 16, wherein the bonding of the conductive bump to the board and the bonding of the metallic member to the board are performed simultaneously.

18. The method of claim 13, wherein the metallic member includes a third surface facing the substrate, a fourth surface facing the board, and a fifth surface connecting the third surface and the fourth surface, the first solder is attached to the third surface of the metallic member, and the second solder is attached to the fourth surface of the metallic member.

19. The method of claim 18, further comprising disposing the first solder and the second solder along the fifth surface to be in contact with the fifth surface of the metallic member.

20. The method of claim 13, further comprising:
forming an isolation member over the board to surround the substrate; and
wherein the metallic member is disposed adjacent to the isolation member.
